(19) United States
(12) Patent Application Publication
(10) Pub. No.: US 2008/0038466 A1
(43) Pub. Date: Feb. 14, 2008

(54) TANTALUM AND NIOBIUM COMPOUNDS AND THEIR USE FOR CHEMICAL VAPOUR DEPOSITION (CVD)

(75) Inventors: Knud Reuter, Krefeld (DE); Stephan Kirchmeyer, Leverkusen (DE); Daniel Gaess, Marburg (DE); Michael Pokoj, Fernwald (DE); Jorg Sundermeyer, Marburg (DE); Wolfgang Stolz, Marburg (DE); Thomas Ochs, Kirchheim-Betziesdorf (DE); Kerstin Volz, Dautphetal (DE)

Correspondence Address: CONNOLLY BOVE LODGE & HUTZ, LLP, P O BOX 2207, WILMINGTON, DE, 19899, US

(73) Assignee: H. C. Starck GmbH, Goslar (DE)

(21) Appl. No.: 11/836,192

(22) Filed: Aug. 9, 2007

(30) Foreign Application Priority Data
Aug. 12, 2006 (DE) 10 2006 037 955.1

(51) Int. Cl. C23C 16/00; C07F 9/00

(52) U.S. Cl. 427/255.394; 556/42

(57) ABSTRACT

The present invention relates to special, novel tantalum and niobium compounds, the use thereof for the deposition of tantalum- or niobium-containing layers by means of chemical vapour deposition and the tantalum- or niobium-containing layers produced by this process.

The present invention relates to special, novel tantalum and niobium compounds, the use thereof for the deposition of tantalum- or niobium-containing layers by means of chemical vapour deposition and the tantalum- or niobium-containing layers produced by this process.

Ta and Ta—N-based mixed system layers for use in Si microelectronics are produced at present by plasma-based deposition processes (physical vapour deposition PVD). In view of the extreme requirements for more and more highly integrated circuits, for example the corresponding layer deposition on structured surfaces, the PVD processes are increasingly reaching the limits of technical feasibility. For these applications, chemical gas-phase depositions (chemical vapour deposition, CVD) down to deposition accurate to the atomic layer by a special CVD process, so-called atomic layer deposition (ALD), are increasingly being used. For these CVD processes, corresponding chemical starting materials of the individual elements must of course be available for the respective desired layers.

At present, halides, such as, for example, TaCl₅, TaBr₅ (cf. WO 2000065123 A1, A. E. Kaloyeros et al., J. Electrochem. Soc. 146 (1999), pages 170-176, or K. Hieber, Thin Solid Films 24 (1974), pages 157-164), are predominantly used for the CVD Ta-based layer structures. This is associated with various disadvantages. Firstly, owing to their corrosive properties, halogen radicals are often undesired for the production of complex layer structures; secondly, the tantalum halides have disadvantages owing to their low volatility and their difficult processibility as high-melting solids. Simple tantalum(V) amides, such as, for example, Ta(N(CH₃)₂)₅, have also been proposed (cf. for example Fix et al., Chem. Mater. 5 (1993), pages 614-619). With the simple amides, however, it is generally possible to establish only certain decomposition ratios of Ta to N which makes it difficult to control the individual element concentrations in the layers exactly. Often, Ta(V) nitride films form (cf. for example Fix et al.: Ta₃N₅) and not the desired electrically conductive Ta(III) nitride layers (TaN). In addition, the films produced with the starting material very often exhibit high, undesired concentrations of carbon. Tsai et al., Appl. Phys. Lett. 67(8), (1995), pages 1128-1130 therefore propose t-BuN═Ta(NEt₂)₃ in TaN CVD at 600° C. Owing to its relatively low volatility, this compound requires a high plant temperature and is therefore not very compatible with the typical production processes for integrated circuits. Other, similar tantalum amide imides were also proposed (cf. for example Chiu et al., J. Mat. Sci. Lett. 11 (1992), pages 96-98), but, without further reactive gas, high carbon contents were produced therewith in the tantalum nitride layers. Recently, further tantalum nitride precursors were proposed, for example by Bleau et al., Polyhedron 24(3), (2005), pages 463-468, which have disadvantages from the outset owing to their complexity and expensive preparation, or special cyclopentadienyl compounds which either inevitably lead to TaSiN (not tantalum nitride) or require an additional, unspecified nitrogen source (Kamepalli et al., US Pat. Appl. Publ. 2004142555 A1, prior. 2003 Jan. 16, ATMI, Inc.). U.S. Pat. No. 6,593,484 (Kojundo Chemicals Laboratory Co., Ltd., Japan) proposes a suitable special tantalum amide imide, but the stated synthesis is difficult and poorly reproducible. Fischer et al., in Dalton Trans. 2006, 121-128, describe mixed hydrazido-amido/imido complexes of tantalum, hafnium and zirconium and a suitability thereof in CVD, but without any indication regarding the Ta:N ratio in the resulting deposition product.

J. Chem. Soc. Dalton Trans. 1990, 1087-1091, describes a trichlorobis(trimethylhydrazido) complex, but there is no indication of the use thereof in CVD.

There is therefore a considerable recognizable need for further, novel precursors for TaN layers which do not have the abovementioned disadvantages or at least provide substantial improvements. For some applications, there may also be the desire for alternative precursors which are more suitable for the corresponding application.

It was therefore the object of the present invention to provide such precursors.

The invention relates to complex tantalum compounds having two monovalent hydrazido ligands of formula (I) which fulfil these preconditions. The hydrazido ligands are those of the general formula

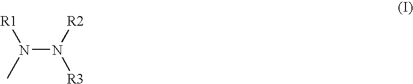

in which
R¹, R² and R³ independently of one another, denote optionally substituted C₁- to C₁₂-alkyl radicals, but not simultaneously methyl, C₅- to C₁₂-cycloalkyl radicals, C₆- to C₁₀-aryl radicals, 1-alkenyl, 2-alkenyl, 3-alkenyl or triorganosilyl radicals —SiR₃, in which R represents C₁- to C₄-alkyl radicals.

The invention furthermore relates to the analogous niobium compounds which are suitable, for example, as CVD precursors for conductive niobium nitride layers (NbN).

The invention relates to compounds of the general formula (II)

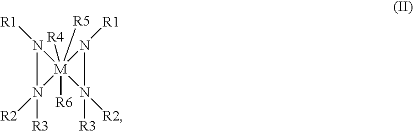

in which
M represents Nb or Ta,
R¹, R² and R³, independently of one another, represent optionally substituted C₁- to C₁₂-alkyl radicals, but not simultaneously methyl radicals, C₅- to C₁₂-cycloalkyl radicals, C₆- to C₁₀-aryl radicals, 1-alkenyl, 2-alkenyl or 3-alkenyl radicals, triorganosilyl radicals —SiR₃, in which R represents C₁- to C₄-alkyl radicals,
R⁴, R⁵, R⁶ represent halogen from the group consisting of Cl, Br and I, represent O—R⁸, in which R⁸ represents an optionally substituted C₁- to C₁₂-alkyl, C₅- to C₁₂-cycloalkyl or C₆- to C₁₀-aryl radical or —SiR₃, represent BH₄, represent an optionally substituted allyl radical, represents an indenyl radical, represent an optionally substituted benzyl radical, represent an optionally substituted cyclopentadienyl radical, represent CH₂SiMe₃, represent a pseudohalide, such as, for example, —N₃, represent silylamide —N(SiMe₃)₂, represent —NR⁹R¹⁰, in which R⁹ and R¹⁰, independently of one another, represent identical or different optionally substituted C₁- to C₁₂-alkyl, C₅- to C₁₂-cycloalkyl or C₆- to C₁₀-aryl radicals, —SiR₃, in which R represents C₁-C₄-alkyl, or H, or represent —NR¹—NR²R³ (hydrazido(1)), in which R¹, R² and R³, independently of one another, have the abovementioned meaning of R¹, R² and R³
or R⁴ and R⁵ together represent ═N—R⁷, in which R⁷ represents an optionally substituted C₁- to C₁₂-alkyl, C₅- to C₁₂-cycloalkyl or C₆- to C₁₀-aryl radical or —SiR₃.

Here, unless mentioned otherwise, substitutes are understood as meaning a substituent with C₁- to C₄-alkoxy or di(C₁- to C₄-alkyl)amino radicals.

Tantalum- and niobium-containing metals, metal alloys, oxides, nitrides and carbides and mixtures thereof and/or compounds in amorphous and/or crystalline form can be produced from the tantalum and niobium compounds according to the invention by means of CVD, ALD (atomic layer deposition) and thermal decomposition. Such mixtures and compounds are used, for example, as dielectric layers in capacitors and gates in transistors, microwave ceramics, piezoceramics, thermal and chemical barrier layers, diffusion barrier layers, hard coatings, electrically conductive layers, antireflection layers, optical layers and layers for IR mirrors. Li tantalates and niobates are an example of optical materials. Examples of electrically conductive and corrosion-resistant layers for electrodes are tantalum- and/or niobium-containing titanium and ruthenium mixed oxides. The tantalum and niobium compounds according to the invention are also suitable as precursors for flame pyrolyses for the production of powders.

Compounds of the general formula (III)

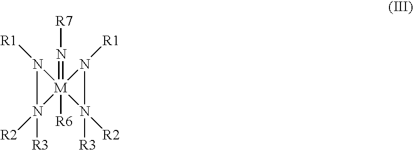

in which
M represents Ta or Nb,
R¹ represents C₁- to C₅-alkyl, C₅- to C₆-cycloalkyl or an optionally substituted phenyl radical or SiR₃, in which R represents C₁-C₄-alkyl,
R² and R³ represent identical C₁- to C₅-alkyl or C₅- to C₆-cycloalkyl radicals or optionally substituted phenyl radicals or SiR₃, in which R represents C₁-C₄-alkyl,
R⁷ represents a C₁- to C₅-alkyl, C₅- to C₆-cycloalkyl or optionally substituted phenyl radical or SiR₃, in which R represents C₁-C₄-alkyl, and
R⁶ represents a halogen radical from the group consisting of Cl, Br and I, represents BH₄, represents an optionally substituted allyl radical, represents an indenyl radical, represents an optionally substituted benzyl radical, represents an optionally substituted cyclopentadienyl radical, represents a C₁- to C₁₂-oxyalkyl radical or represents a radical NR⁹R¹⁰, in which R⁹ and R¹⁰, independently of one another, represent identical or different optionally substituted C₁- to C₁₂-alkyl, C₅- to C₁₂-cycloalkyl or C₆- to C₁₀-aryl radicals, —SiR₃, in which R represents C₁-C₄-alkyl, or H,

are preferred.

Compounds of the general formula (IV)

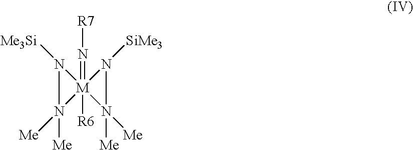

in which
R⁷ represents a radical from the group consisting of the C₁- to C₅-alkyl radicals, a C₆- to C₁₀₋aryl radical optionally substituted by one to three C₁- to C₅-alkyl groups, or SiR₃, in which R represents C₁-C₄-alkyl, and
R⁶ represents a halogen radical from the group consisting of Cl, Br and I, represents BH₄, represents an optionally substituted allyl radical, represents an indenyl radical, represents an optionally substituted benzyl radical, represents an optionally substituted cyclopentadienyl radical, represents a C₁- to C₁₂-oxyalkyl radical or represents a radical —NR⁹R¹⁰, in which R⁹ and R¹⁰, independently of one another, represent identical or different optionally substituted C₁- to C₁₂-alkyl, C₅- to C₁₂-cycloalkyl or C₆- to C₁₀-aryl radicals, —SiR₃, in which R represents C₁-C₄-alkyl, or H,

are particularly preferred.

Compounds of the general formula (V)

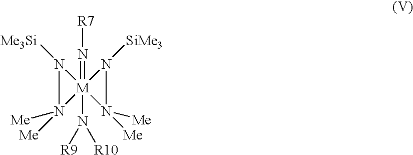

in which
R⁹ and R¹⁰ independently of one another, represent an identical or different radical from the group consisting of the C₁- to C₅-alkyl radicals, C₆-C₁₀-aryl radicals optionally substituted by one to three C₁-C₅-alkyl groups, or SiR₃, in which R represents C₁-C₄-alkyl, or H and
R⁷ represents a radical from the group consisting of the C₁- to C₅-alkyl radicals, C₆-C₁₀-aryl radicals optionally substituted by one to three C₁- to C₅-alkyl groups, or SiR₃, in which R represents C₁-C₄-alkyl,

are very particularly preferred.

Compounds of the formulae (VI) to (X)

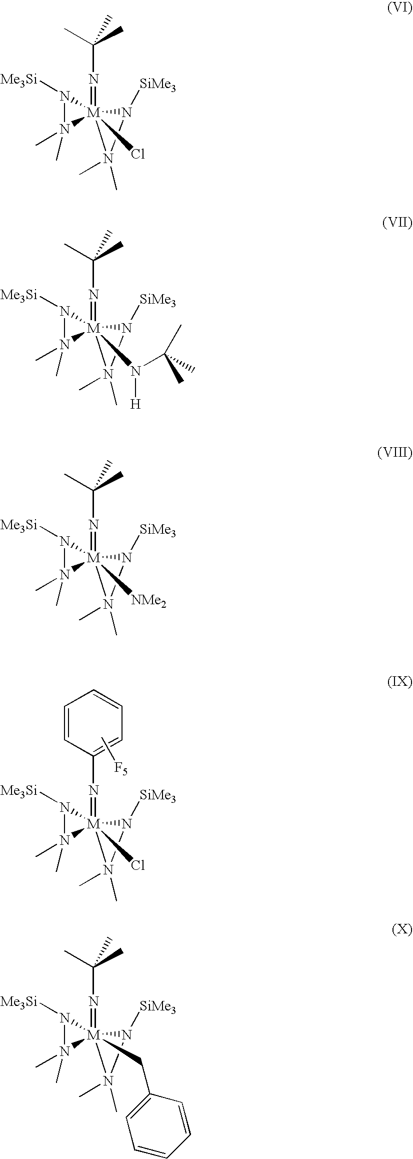

in which M represents Ta or Nb,

are likewise very particularly preferred.

In each case the tantalum compounds (M=Ta) are very particularly preferred.

Alkyl or alkoxy, in each case independently, represents a straight-chain, cyclic or branched alkyl or alkoxy radical, it being possible for said radicals to be optionally further substituted. The same applies to the alkyl moiety of a trialkylsilyl or mono- or dialkylamino radical or the alkyl moiety of mono- or dialkylhydrazines or mono-, di-, tri- or tetralkylsilanes.

C₁-C₄-Alkyl in the context of the invention represents, for example, methyl, ethyl, n-propyl, isopropyl, n-butyl, sec-butyl or tert-butyl, C₁-C₅-alkyl additionally represents, for example, n-pentyl, 1-methylbutyl, 2-methylbutyl, 3-methylbutyl, neopentyl, 1-ethylpropyl, 1,1-dimethylpropyl or 1,2-dimethylpropyl, C₁-C₆-alkyl additionally represents, for example, n-hexyl, 1-methylpentyl, 2-methylpentyl, 3-methylpentyl, 4-methylpentyl, 1,1-dimethylbutyl, 1,2-dimethylbutyl, 1,3-dimethylbutyl, 2,2-dimethylbutyl, 2,3-dimethylbutyl, 3,3-dimethylbutyl, 1-ethylbutyl, 2-ethylbutyl, 1,1,2-trimethylpropyl, 1,2,2-trimethylpropyl, 1-ethyl-1-methylpropyl, 1-ethyl-2-methylpropyl or 1-ethyl-2-methylpropyl, C₁-C₁₂-alkyl additionally represents, for example, n-heptyl and n-octyl, n-nonyl, n-decyl and n-dodecyl.

1-Alkenyl, 2-alkenyl and 3-alkenyl represent, for example, the alkenyl groups corresponding to the above alkyl groups. C₁-C₄-Alkoxy represents, for example, the alkoxy groups corresponding to the above alkyl groups, such as, for example, methoxy, ethoxy, n-propoxy, isopropoxy, n-butoxy, sec-butoxy or tert-butoxy.

C₅-C₁₂-Cycloalkyl represents, for example, optionally substituted mono-, bi- or tricyclic alkyl radicals. Cyclopentyl, cyclohexyl, cycloheptyl, pinanyl, adamantyl, the isomeric menthyls, n-nonyl, n-decyl and n-dodecyl may be mentioned as examples. Cyclopentyl and cyclohexyl are preferred as C₅-C₆-cycloalkyl,

Aryl, in each case independently, represents an aromatic radical having 6 to 14, preferably 6 to 10, skeletal carbon atoms, in which no skeletal carbon atom, one skeletal carbon atom or two or three skeletal carbon atoms per cycle can be substituted by heteroatoms selected from the group consisting of nitrogen, sulphur and oxygen, but preferably represent a carbocyclic aromatic radical having 6 to 14, preferably 6 to 10, skeletal carbon atoms. Examples of optionally substituted C₆-C₁₀-aryl are phenyl, 2,6-diisopropylphenyl, o-, p-, m-tolyl or naphthyl.

Furthermore, the carbocyclic aromatic radical or heteroaromatic radical may be substituted by up to five identical or different substituents per cycle, which are selected from the group consisting of fluorine, cyano, C₁-C₁₂-alkyl, C₁-C₁₂-fluoroalkyl, C₁-C₁₂-fluoroalkoxy, C₁-C₁₂-alkoxy and di(C₁-C₈-alkyl) amino.

The compounds according to the invention can be prepared in a simple manner by reacting magnesium derivatives of hydrazido ligand precursors of the general formula (XI)

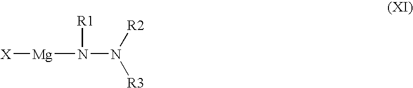

in which R¹, R² and p³ have the abovementioned meaning and X is either a halogen from the group consisting of Cl, Br and I or a ligand of the general formula (I),

with Ta or Nb complexes of the general formula (XII)
[M(R⁴)(R⁵)(R⁶)Cl₂L₂] (XII)

in which
M represents Ta or Nb,
L represents a complex ligand selected from aliphatic or aromatic amines, heterocyclic amines, preferably pyridine, ethers, halide, preferably chloride, or nitrites, preferably acetonitrile, but it also being possible for L₂ to be absent, and
R⁴, R⁵ and R⁶ have the abovementioned meaning,

in a suitable solvent, preferably at a temperature of −20° C. to 120° C.

Suitable solvents are, for example, ethers, such as, for example, THF, diethyl ether or 1,2-dimethoxyethane, dipolar aprotic solvents, such as, for example, acetonitrile, N,N-dimethylformamide or tert-amines, halogenated aliphatic or aromatic hydrocarbons, such as CH₂Cl₂, CHCl₃ or chlorobenzene, or aliphatic or aromatic hydrocarbons, such as, for example, toluene, pentane, hexane, etc., and mixtures of these or mixtures with optionally further solvents. The Ta or Nb complexes of the general formula (XII) [M(R⁴)(R⁵)(R⁶)Cl₂L₂] can be prepared in isolated form or in situ by generally known processes.

Instead of the magnesium compounds of the formula (XI), it is optionally also possible to use other metal derivatives of the hydrazido ligands, for example alkali metal salts, for example of lithium.

It is furthermore possible to convert hydrazido complexes according to the invention into other compounds according to the invention by exchange of ligands. For example an imino ligand can be exchanged for another ligand by reaction of the corresponding amine.

Finally, for example, hydrazido complexes according to the invention which still contain halogen ligands can be converted with alkali metal salts of amines, such as, for example, lithium amides, into other hydrazido complexes according to the invention.

For isolation of the compounds according to the invention, the solvent is removed, for example by distilling off under reduced pressure, and further purification by means of washing or subsequent drying may follow. Such suitable methods are known to the person skilled in the art.

The invention furthermore relates to the use of compounds according to general formula (II) as a precursor for tantalum nitride (TaN) layers or niobium nitride (NbN) layers by means of chemical vapour deposition and the TaN or NbN layers produced accordingly from the compounds of the general formula (II). Preferably compounds of the general formula (III), particularly preferably compounds of the general formula (IV) and very particularly preferably compounds of the formulae (VI) to (X) are to be used in this process. The definition of the radicals corresponds here to the abovementioned definitions.

The invention furthermore relates to substrates which have a TaN or an NbN layer which is produced from the compounds of the general formula (II) or preferably of the general formula (III) with the abovementioned definitions for the various radicals.

The compounds according to the present invention have the following technical advantages:
1) The introduction of the hydrazido ligands as a CVD-suitable leaving group for Ta(III) or Nb(III) layers reduces the danger of undesired C incorporation into the substrate coating.
2) In combination with N starting materials, for example hydrazine derivatives (1,1-dimethylhydrazine or tert-butylhydrazine) and ammonia, a targeted change of the layer composition is possible in the case of CVD.
3) By using two hydrazido ligands the formation of the oxidation state of Ta or Nb in the deposited layer can be promoted towards Ta(III) or Nb(III) compounds in a targeted manner.

The invention also relates to the use of the Ta and Nb compounds according to the invention for the deposition of Ta- or Nb-containing layers, optionally with admixture of further compounds, for establishing certain concentrations of the respective elements in a defined manner in the layer by means of chemical vapour deposition (CVD) with subsequent process steps: a suitable substrate, such as, for example, an Si wafer or an Si wafer already having further surface-structured individual or multiple layers, as typically used for the production of Si-based integrated circuits, is introduced into a CVD unit and heated to a temperature in the range of 250° C. to 700° C., suitable for layer deposition. A carrier gas is laden with starting materials in defined concentrations, it being possible to use inert gases, such as, for example, N₂ and/or Ar, also in combination with inert, vaporized solvents, such as, for example, hexane, heptane, octane, toluene or butyl acetate, as carrier gas and it also being possible to add reactive, e.g. reducing, gases, such as, for example, H₂. The laden carrier gas is passed for a defined duration of exposure over the surface of the heated substrate, the respective concentrations of starting materials and the duration of exposure being matched to one another with the proviso that a Ta- or Nb-containing layer having a predetermined layer thickness and a predetermined composition is formed on the surface of the substrate, either in amorphous, nanocrystalline, microcrystalline or polycrystalline form.

Typical durations of exposure, depending on the deposition rate, are, for example, a few seconds to several minutes or hours. Typical deposition rates may be, for example, from 0.1 nm/sec to 1 nm/sec. However, other deposition rates are also possible. Typical layer thicknesses are, for example, 0.1 to 100 nm, preferably 0.5 to 50 nm, particularly preferably 1 to 10 nm.

In CVD technology, in addition to the starting materials according to general formula (II), preferably general formulae (III) to (X), for the production of pure Ta or Nb metal layers (Ta- or Nb-rich single layers), Ta- or Nb-rich layers as well as Ta—N- or Nb—N-containing mixed layers, the following starting materials are advantageously also used for establishing the N concentration of Ta—N- or Nb—N-containing mixed system layers—also referred to below as N starting materials—in a targeted manner: ammonia (NH₃) or mono(C₁-C₁₂-alkyl)hydrazines, in particular tert-butylhydrazine (^{t}Bu-NH—NH₂), and/or 1,1-di (C₁-C₆-alkyl)-hydrazine, in particular 1,1-dimethylhydrazine ((CH₃)₂N—NH₂) it being possible for the alkyl groups to be linear or branched. Particularly for influencing the stability of the produced mixed system layers in subsequent high-temperature heating steps, it may be advantageous to admix further elements in a CVD deposition in order to influence the recrystallization behaviour of the layer formed. For use in Si-based integrated circuits, the element Si is particularly suitable for this purpose. In addition to the starting materials discussed above, the following starting materials for Si—also referred to below as Si starting materials—are advantageously used in CVD technology for the production of Ta (or Nb)—N—Si-containing mixed system layers: silane (SiH₄) and/or disilane (Si₂H₆) and/or mono(C₁-C₁₂-alkyl)silanes, in particular tert-butylsilane (tBuSiH₃), and/or di(C₁-C₁₂-alkyl)silanes, in particular di-tert-butylsilane (tBu₂SiH₂), and/or tri(C₁-C₁₂-alkyl)silanes, in particular triethylsilane ((C₂H₅)₃SiH), and/or tetra(C₁-C₁₂-alkyl)silanes, in particular tetraethylsilane ((C₂H₅)₄Si), it being possible for the alkyl groups to be linear or branched.

In principle, precise concentrations of the starting materials depend on the thermal decomposition properties of the respective starting materials in the CVD process. The starting materials are preferably used in the following molar ratios: N starting material/Ta or Nb starting material 0 to 20 000, Si starting materials/Ta or Nb starting materials 0-100. The surface temperature of the substrate is preferably adjusted to the range from 300° C. to 600° C. The total pressure of carrier gas and starting materials is preferably adjusted to pressures in the range from 10 hPa to 1000 hPa, the ratio of the partial pressure of the sum of all starting materials to the partial pressure of the carrier gas being from 0.0001 to 0.5. The deposition rate is preferably 0.05 nm/min to 50 nm/min.

The tantalum and niobium compounds according to the invention are also suitable as precursors for tantalum oxide (Ta₂O5) layers or niobium oxide (Nb₂O₅) layers, which are of interest, for microelectronics on account of their high dielectric constant.

The following examples serve for explaining the invention by way of example and not as a limitation.

### EXAMPLES

In the following examples, the abbreviations and abbreviated compound names denote the following structures:

^{t}Bu=tert-butyl

^{t}BuN=tert-butylimino=^{t}Bu-N=

Me=methyl

Py=pyridine

Bz=benzyl

### Examples of the Preparation of Precursors Not According to the Invention

### Precursor Example A

### Preparation of RN(SiMe₃)NMe₂

60 ml (47 g, 0.78 mmol) of 1,1-dimethylhydrazine were initially taken in 500 ml of pentaner and 50 ml (43 g, 0.40 mmol) of chlorotrimethylsilane were slowly added. After complete addition, the reaction solution was heated under reflux for 3 hours and then filtered. The filtration residue was washed with 60 ml of pentane, and the combined filtrates were distilled under argon. The second fraction (99° C.) gave 42.12 g (0.32 mmol; 81%) of the colourless liquid.

¹H-NMR (300 MHz, CDCl₃): 2.22 ppm (6H, N(CH₃)₂), 1.78 pm (1, NH), −0.09 ppm (9H, Si(CH₃)₃). ¹³C{¹H} NMR (75 MHz, CDCl₃): 52.4 ppm (N(CH₃)₂), −0.8 ppm (Si (CH₃)₃). IR (nujol mull, cm⁻¹) 3284 m, 2985 s, 2950 s, 2895 s, 2849 s, 2811 s, 2763 s, 1462 m, 1450 s, 1434 m, 1399 m, 1247 s, 1153 m, 1062 s, 1009 m, 895 s, 838 s, 747 m, 720 m, 685 m, 614 m, 493 m, 445 w

### Precursor Example B

### Preparation of [Mg(N(SiMe₃)NMe₂)Br]

4.21 g (173 mmol) of Mg were heated in vacuo in a three-necked flask and 600 ml of diethyl ether were added. 24.8 ml (31.2 g; 228 mmol) of 2-bromobutane were added dropwise through a septum. After dissolution of magnesium, 23.0 g (174 mmol) of HN(SiMe₃)NMe₂ were added dropwise. The suspension was stirred for 12 hours and concentrated at 20 mbar to ⅔ of its volume before the colourless solid was filtered off and dried.

Yield: 37.2 g (158 mmol; 91%). IR (nujol mull, cm⁻¹): 1249 m, 1242 m, 1012 m, 981 m, 871 m, 842 m, 771 m, 756 m, 673 m, 468 m

### Precursor Example C

### Preparation of [Mg(N(SiMe₃)NMe₂)Cl]

1.0 g (41.14 mmol) were heated in vacuo in a three-necked flask and 60 ml of diethyl ether were added. 5.6 ml (4.9 g; 53.2 mmol) of 1-chlorobutane were added through a septum. After dissolution of magnesium, 5.3 g (43.8 mmol) of HN(SiMe₃)NMe₂ were added dropwise through a septum. The suspension was stirred for 12 hours and concentrated at 20 mbar to ⅔ of its volume before the colourless solid was filtered off and dried.

Yield: 6.8 g (35.6 mmol; 87%). IR (nujol mull, cm⁻¹): 1249 m, 1242 m, 1012 m, 981 m, 871 m, 842 m, 771 m, 756 m, 673 m, 468 m

### Precursor Example D

### Preparation of [Ta(^{t}BuN)(^{t}BuNH)Cl₂·2Py]

61.3 ml of ^{t}BuNH₂ (587 mmol) in 50 ml of CH₂Cl₂ were added dropwise to a suspension of 21.0 g of TaCl₅ (58.7 mmol) in 200 ml of CH₂Cl₂ while cooling with ice. The reaction mixture was then heated to 23° C. and stirred for 4 h. The suspension obtained was cooled again with an ice bath and a solution of 23.7 ml (294 mmol) of pyridine in 50 ml of CH₂Cl₂ was added. After stirring for 4 h at 23° C., 150 ml of hexane were added to the reaction mixture and the solution obtained was filtered through Celite. The residue was washed twice with 100 ml of 1:1 CH₂Cl₂/hexane each time until colourless. The combined solutions were freed at 20 mbar from all volatile constituents and the residue was washed with hexane and dried. Pale yellow, microcrystalline product, yield 25.9 g (84% of theory), melting point >120° C. (decomposition).

Elemental analysis:

Calculated (%) for C₁₈H₂₉N₄Cl₂Ta (M=553.31 g·mol⁻¹): C, 39.07; H, 5.28; N, 10.13.

Found: (%): C, 40.15; H, 5.17; N, 10.02.

MS-EI: 379 (M⁺−2 Py−Me, 20%), 323 (M⁺−2 Py−(CH₃)₂CCH₂−Me, 42%), 41 (100%).

¹H-NMR (300.1 MHz, CDCl₃): δ=1.28 (s, 9H, NHC(CH₃)₃), 1.31 (s, 9H, NC(CH₃)₃), 7.44 (pseudo-t, 4H, m-H_{py}), 7.86 (tt, J₁=7.7 Hz, J₂=1.5 Hz, 2H, p-H_{py}), 8.60 (broad s, 1H, NHC(CH₃)₃), 9.40 (dd, J₁=6.9 Hz, J₂=1.5 Hz, 4H, o-H_{py})

¹³C{¹H}-NMR (CDCl₃, 75 MHz, 300 K): 32.3 (NC(CH₃)₃), 33.9 (NHC(CH₃)₃), 56.4 (NHC(CH₃)₃), 64.8 (s, NC(CH₃)₃), 124.1 (m-Py), 139.2 (P-Py), 153.5 (o-Py).

### Examples According to the Invention

### Example 1

### Preparation of [Ta(N(SiMe₃)NMe₂)₂Cl₃]

5.2 g (9.94 mmol) of [Ta(NtBu)C₁₃PY₂] (Precursor Example D) were initially taken in 30 ml of CH₂Cl₂, and 2.9 g (21.86 mmol) of HN(SiMe₃)NMe₂ (Precursor Example A) were added before stirring was effected for 10 hours. The orange suspension was filtered and the residue was washed with 4 ml of toluene. The combined filtrates were dried in vacuo and the residue on evaporation was digested with 100 ml of hexane. This was filtered off and dried in vacuo.

Yield: 5.344 g (9.72 mmol, 97%). ¹H-NMR (300 MHz, C₆D₆): 3.08 ppm (6H, N(CH₃)₂), 0.17 ppm (9H, Si (CH₃)₃). ¹³C{¹H}-NMR (75 MHz, C₆D₆): 52.9 ppm (N(CH₃)₂) 0.17 ppm (Si (CH₃)₃).

Elemental analysis C₁₀H₃₀N₄Cl₃Si₂Ta: Theoretical: C, 21.48; H, 5.50; N, 10.19. Found: C, 10.42; H, 5.22; N, 10.42. EI-MS (assignment, % relative intensity): 550 [{M⁺}, 0.1], 417 [{M-(N(SiMe₃)NMe₂)}⁺, 25.5], 131 [{N(SiMe₃)NMe₂)⁺, 49.9]. IR (nujol mull, cm⁻¹): 1248 s, 1168 w, 1041 s, 1006 s, 910 s, 893 m, 844 s, 773 m, 734 m, 723 m, 696 m, 634 m, 501 s, 472 w

### Example 2

### Preparation of [Ta(NtBu)(N(SiMe₃)NMe₂)₂Cl]

a) 4.0 g (7.7 mmol) [Ta(NtBu)C₁₃Py₂] (Precursor Example D) and 2.2 g (3.86 mmol) of [Mg(N(SiMe₃)NMe₂)₂] were cooled to −78° C. before 40 ml of THF were added. The mixture was stirred for 4 hours and then brought to 23° C. After 12 hours the volatile constituents were removed at 20 mbar and the residue was digested with 40 ml of hexane. The suspension was filtered and the residue was washed twice with 40 ml of hexane. The combined filtrates were evaporated to dryness and the residue on evaporation was sublimed (103 mbar, 70° C.)

Yield: 3.53 g (6.42 mmol, 83%)

b) 10 ml of THF were added to 1.0 g (1.93 mmol) [Ta(NtBu)Cl₃Py₂] (Precursor Example D) and 740 mg (3.87 mmol) of [Mg(N(SiMe₃)NMe₂)Cl] (Precusor Example C) at −78° C. The reaction mixture was stirred for four hours and then brought to 23° C. After 12 hours, the solvent was removed and the residue was extracted with 30 ml of hexane. The filtration residue was washed twice with 5 ml of hexane each time and the combined filtrates were brought to dryness in vacuo. The orange residue was sublimed (10⁻³ mbar, 70° C.).

Yield: 670 mg (1.22 mmol, 63%). ¹H-NMR (300 MHz, C₆D₆): 2.69 ppm (6H, N(CH₃)₂), 2.46 ppm (6H, N(CH₃)₂), 1.40 ppm (9H, NC(CH₃)₃), 0.25 ppm (18H, Si(CH₃)₃). ¹³C{¹H} NMR (75 MHz, C₆D₆): 63.9 ppm (NC(CH₃)₃), 51.6 ppm (N(CH₃)₂), 51.1 ppm (N(CH₃)₂), 34.1 ppm (NC(CH₃)₃), 2.8 ppm (Si(CH₃)₃). Elemental analysis: C₁₄H₃₉N₅ClSi₂Ta Theoretical: C, 30.57; H, 7.15; N, 12.73. Found: C, 29.70, H, 7.34; N, 12.03. EI-MS (assignment, % relative intensity): 549 [{M)⁺, 5.5], 534 ({M-CH₃}⁺, 100], 492 [({M-C₄H₉}⁺, 3.9], 131 [{(Me₃Si)NNMe₂}⁺, 18.6], 73 [{SiMe₃}⁺, 51.5], 58 [{NNMe₂}⁺, 9.9], 44 [{NMe₂}⁺, 2.4]. IR (nujol mull, cm⁻¹): 1351 m, 1279 s, 1246 s, 1211 m, 1055 s, 1031 s, 902 s, 838 s, 785 m, 774 m, 715 m, 683 S, 634 m, 537 m, 480 s.

### Example 3

### Preparation of [Nb(NtBu)(N(SiMe₃)NMe₂)₂Cl]

300 ml of THF were added to 21.38 g (49.9 mmol) of [Nb(Ntu)C₁₃Py₂] (prepared analogously to Precursor Example D) and 19.18 g (100.4 mmol) of [Mg(N(SiMe₃)NMe₂)Cl] (Precursor Example C) at −78° C. The reaction mixture was brought to 23° C. after four hours and stirred for a further 8 hours. The suspension was evaporated to dryness and extracted with 250 ml of hexane. The filtration residue was washed twice with 100 ml of hexane and the combined filtrates were freed of volatile constituents at 20 mbar. The orange oil was distilled (10⁻³ mbar, 130° C.).

Yield: 17.3 g (37.4 mmol, 76%).

¹H-NMR (300 MHz, C₆D6): 2.65 ppm (6H, N(CH₃)₂), 2.53 ppm (6H, N(CH₃)₂), 1.30 ppm (9H, NC(CH₃)₃), 0.30 ppm (18H, Si(CH₃)₃), ¹³C{¹H}-NMR (75 MHz, C₆D₆): 65.8 ppm (NC(CH₃)₃), 52.9 ppm (N(CH₃)₂), 52.7 ppm (N(CH₃)₂), 35.5 ppm (NC(CH₃)₃), 2.9 ppm (Si(CH₃)₃). Elemental analysis C₁₄H₃₉N₅ClSi₂Nb Theoretical: C, 36.39; H, 8.51; N, 15.16; Found: C, 36.05; H, 8.38; N, 15.15. ESI-MS (assignment, % relative intensity): 462 [{M}⁺, 0.1], 446 [{M-CH₃}⁺, 18.9], 403 [, 3.9], 132 [{H(Me₃Si)NNMe₂}⁺, 9.6], 131[{(Me₃Si)NNMe₂}⁺, 14.6], 73 [{SiMe₃}⁺, 76.8], 59 [{HNNMe₂}⁺, 6.0], 58 [{NNMe₂}⁺, 12.5], 44 [{NMe₂}⁺, 29.8]. IR (nujol mull, cm⁻¹): 1351 m, 1279 s, 1246 s, 1211 m, 1055 s, 1031 s, 902 s, 838 s, 785 m, 774 m, 715 m, 683 s, 634 m, 537 m, 480 s.

### Example 4

### Preparation of [Ta(NtBu) (N(SiMe₃)NMe₂)₂Br]

300 ml of THF were added to 33.5 g (64.8 mmol) of [Ta(NtBu)Cl₃Py₂] (Precursor Example D) and 30.6 g (129.9 mmol) of [Mg(N(SiMe₃)NMe₂)Br] (Example B) at −50° C. After four hours, the mixture was heated to 23° C. and stirred for a further 10 hours. The suspension was freed of volatile constituents at 20 mbar and extracted with 300 ml of hexane. The filtration residue was washed twice with 200 ml of hexane each time before the combined filtrates were brought to dryness. The residue on evaporation was sublimed (10⁻³ mbar, 70° C.).

Yield: 26.04 g (43.8 mmol, 68%), slightly contaminated.

¹H-NMR (300 MHz, C₆D₆): 2.70 ppm (6H, N(CH₃)₂), 2.46 ppm (6H, N(CH₃)₂), 1.41 ppm (9H, NC(CH₃)₃), 0.25 ppm (18H, Si(CH₃)₃), ¹³C{¹H}-NMR (75 MHz, C₆D₆): 63.9 ppm (NC(CH₃)₃), 51.6 ppm (N(CH₃)₂), 51.1 ppm (N(CH₃)₂), 34.1 ppm (NC(CH₃)₃), 2.8 ppm (Si(CH₃),₃). EI-MS (assignment, % relative intensity): 580 [{M-CH₃}⁺, 19.3], 131 [{H(Me₃Si)NNMe₂}⁺, 18.6], 73 [{SiMe₃}⁺, 51.5], 58 [{NNMe₂)⁺, 12.6], 44 [{NMe₂}⁺, 14.9]. IR (nujol mull, cm⁻¹): 1351 m, 1279 s, 1246 s, 1211 m, 1055 s, 1031 s, 902 s, 838 s, 785 m, 774 m, 715 m, 683 s, 634 m, 537 m, 480 s.

### Example 5

### Preparation of [Nb(NtBu)(N(SiMe₃)NMe₂)₂Br]

5 ml of THF were added to 150 mg (0.35 mmol) of [Nb(NtBu)Cl₃Py₂] (prepared analogously to Precursor Example D) and 255 mg (1.08 mmol) of [Mg(N(SiMe₃)NMe₂)Br] (Precursor Example B) at −78° C. and the mixture was heated to room temperature after four hours. After 12 hours, the mixture was evaporated to dryness and extracted with 15 ml of hexane. The filtration residue was washed with twice 5 ml of hexane and the filtrates were freed from volatile constituents. The orange oil was distilled (10⁻³ mbar, 120° C.).

Yield: 104 mg (0.21 mmol, 60%). ¹H-NMR (300 MHz, C₆D₆): 2.65 ppm (6H, N(CH₃)₂), 2.54 ppm (6H, N(CH₃)₂), 1.27 ppm (9H, NC(CH₃)₃), 0.30 ppm (18H, Si(CH₃)₃), ¹³C{¹H}-NMR (75 MHz, C₆D₆): 66.3 ppm (NC(CH₃)₃), 53. 5 ppm (N(CH₃)₂), 53.1 ppm (N(CH₃)₂), 32.3 ppm (NC(CH₃)₃), 2.9 ppm (Si(CH₃)₃), Elemental analysis for C₁₄H₃₉N₅BrSi₂Nb Theoretical: C, 33.20; H, 7.76; N, 13.83; Found: C, 32.88; H, 7.51; N, 13.78. EI-MS (assignment, % relative intensity): 492 [{M-CH₃}⁺, 10.4], 449 [{M-NNMe₂}⁺, 3.3], 131 [{(Me₃Si)NNMe₂}⁺, 30.9], 73 [{SiMe₃}⁺, 100.0], 58 [{NNMe₂}⁺, 17.7], 44 [{NMe₂}⁺, 52.0]. IR (nujol mull, cm⁻¹): 1351 m, 1279 s, 1246 s, 1211 m, 1055 s, 1031 s, 902 s, 838 s, 785 m, 774 m, 715 m, 683 s, 634 m, 537 m, 480 s.

### Example 6

### Preparation of [Ta(NC₆F₅)(N(SiMe₃)NMe₂)₂Cl]

669 mg (1.21 mmol) of [Ta(NtBu)(N(SiMe₃)NMe₂)₂Br] (Example 4) and 224 mg (1.22 mmol) of pentafluoroaniline were dissolved in 5 ml of hexane. The mixture was stirred at 60° C. for 18 hours. The product was precipitated from the reaction solution at −20° C. Successive concentration and precipitation at −20° C. gave 620 mg (0.94 mmol, 77%) of the product.

¹H-NMR (300 MHz, C₆D₆): 2.64 ppm (6H, N(CH₃)₂), 2.40 ppm (6H, N(CH₃)₂), 0.16 ppm (9H, Si(CH₃)₃). ¹³C{¹H}-NMR (75 MHz, C₆D₆): 51.5 ppm (N(CH₃)₂), 50.9 ppm (N(CH₃)₂), 2.0 ppm (Si(CH₃)₃). ¹⁹F-NMR (282 MHz, C₆D₆): −135.9 ppm (psd, 2F, o-F), −167.0 (pst, 2F, m-F), −170.9 (pst, 1F, p-F). Elemental analysis for C₁₆H₃₀N₅ClSi₂Ta Theoretical: C, 29.12; H, 4.58; N, 10.16; Found: C, 28.23; H, 4.78; N, 9.81. EI-MS (assignment, relative intensity): 183 [{C₆F₅NH₂}⁺, 22.0], 131 [{N(SiMe₃)NMe₂}⁺, 1.01, 73 [{SiMe₃}⁺, 36.7], 44 [{NMe₂}⁺, 53.9]. IR (nujol mull, cm⁻¹): 1460 s, 1332 m, 1251 s, 1224 m, 1045 s, 1026 s, 983 m, 900 s, 841 s, 777 w, 751 w, 721 w, 684 w, 634 w, 482 w.

### Example 7

### Preparation of [Nb(NC₆F₅)(N(SiMe₃)NMe₂)₂Cl]

1.5 g (3.2 mmol) of [Nb(NtBu)(N(SiMe₃)NMe₂)₂Br] (Example 5) were dissolved in 15 ml of toluene and added to 603 mg (3.2 mmol) of pentafluoroaniline. The mixture was stirred at 60° C. for 18 hours. The product was precipitated from the reaction solution at −20° C. Successive concentration and precipitation at −20° C. gave 1.02 g (1.79 mmol, 55%) of the product.

¹H-NMR (300 MHz, C₆D₆): 2.64 ppm (6H, N(CH₃)₂), 2.45 ppm (6H, N(CH₃)₂), 0.22 ppm (9H, Si(CH₃)₃). ¹³C{¹H}-NMR (75 MHz, C₆D₆): 52.2 ppm (N(CH₃)₂), 51.8 ppm (N(CH₃)₂), 2.1 ppm (Si(CH₃)₃). ¹⁹F-NMR (282 MHz, C₆D₆): −152.8 ppm (psd, 2F, o-F), −166.4 (pst, 2F, m-F), −168.7 (pst, 1F, p-F). Elemental analysis for C₁₆H₃₀N₅ClF₅Si₂Nb Theoretical: C, 33.60; H, 5.29; N, 12.24; Found: C, 33.23; H, 5.08; N, 11.82. EI-MS (assignment, % relative intensity): 183 [{C₆F₅NH₂}⁺, 2.74], 131 [{N(SiMe₃)NMe₂}⁺, 6.15], 73 [{SiMe₃}⁺, 92.4], 44 [{NMe₂}⁺, 58.9]. IR (nujol mull, cm⁻¹): 1500 s, 1458 s, 1327 m, 1248 s, 1217 s, 1168 m, 1047 s, 985 s, 898 s, 839 s, 769 m, 720 m, 713 m, 680 m.

### Example 8

### Preparation of [Ta(NtBu)(N(SiMe₃)NMe₂)₂Bz]

8 ml of toluene were added to 500 mg (0.84 mmol) of (Ta(NtBu)(N(SiMe₃)NMe₂)₂Br] (Example 4) and 127 mg (0.97 mmol) of BzK at 0° C. After 1 hour, the mixture was heated to room temperature and stirred for 17 hours. The suspension was dried in vacuo and extracted with 20 ml of hexane. The filtrate was evaporated to dryness and sublimed (70° C., 10⁻³ mbar).

Yield: 465 mg (0.77 mmol, 91%). ¹H-NMR (300 MHz, C₆D6): 7.53 ppm (d, 2H, o-H), 7.28 ppm (t, 2H, m-H), 6.94 ppm (t, 1H, p-H), 2.41 (s, 2H, Ph-CH₂—Ta), 2.35 ppm (s, 12H, N(CH₃)₂), 1.44 ppm (s, 9H, NC(CH₃)₃), 0.24 ppm (s, 9H, Si(CH₃)₃) ¹³C{¹H}-NMR (75 MHz, C₆D₆): 153.5 ppm (Bz), 128.9 ppm (Bz), 121.2 ppm (Bz), 63.6 ppm (NC(CH₃)₃), 51.2 ppm (N(CH₃)₂), 50.8 ppm (N(CH₃)₂, 49.7 ppm (Ph-CH₂—Ta), 3.0 ppm (Si(CH₃)₃). Elemental analysis for C₂₁H₄₆N₅Si₂Ta Theoretical: C, 41.64; H, 7.65; N, 11.56; Found: C, 41.03; H, 7.34; N, 10.83. EI-MS (assignment, % relative intensity): 514 [{M-C₇H₇}⁺, 10.0], 471 [{M-C₇H₇—NMe₂}⁺, 6.6], 91 [{C₇H₇}⁺, 23.3], 73 [{SiMe₃}⁺, 26.1], 58 [{NNMe₂}, 7.8]. IR (nujol mull, cm⁻¹): 3059 w, 1596 m, 1485 w, 1351 w, 1275 s, 1246 s, 1209 m, 1053 s, 1026 s, 898 s, 838 s, 743 m, 716 w, 697 m, 480 m.

### Example 9

### Preparation of [Nb(NtBu)(N(SiMe₃)NMe₂)₂Bz]

A solution of 512 mg (3.9 mmol) of BzK in 15 ml of toluene were added to 1.57 g (3.3 mmol) of [Nb(NtBu)(N(SiMe₃)NMe₂)₂)Br] (Example 5) at 0° C. After one hour, the mixture was heated to room temperature and stirred for 17 hours. The volatile constituents were removed at 20 mbar and the residue on evaporation was extracted with 20 ml of hexane. The filtrate was concentrated and the product was precipitated at −20° C. Yield: 1.43 g (2.77 mmol, 81%). For further purification the product can be sublimed at 9° C. (10⁻³ mbar).

¹H-NMR (300 MHz, C₆D₆): 7.50 ppm (pseudo-d, ³J_{H,H}=7.2 Hz, 2H, o-H), 7.25 ppm (t, 2H, ³J_{H,H}=7.5 Hz, m-H), 6.94 ppm (t, 1H, ³J_{H,H}=7.2 Hz, p-H), 2.71 (s, 2H, Ph-CH₂), 2.37 ppm (s, 6H, N(CH₃)₂), 2.34 ppm (s, 6H, N(CH₃)₂), 1.37 ppm (s, 9H, NC(CH₃)₃), 0.26 ppm (s, 9H, Si(CH₃)₃). ¹³C{¹H}-NMR (126 MHz, C₆D₆): 154.3 ppm (i-Bz), 128.4 ppm (o-Bz), 127.8 ppm (m-Bz), 120.6 ppm (p-Bz), 64.3 ppm (NC(CH₃)₃), 51.6 ppm (N(CH₃)₂), 51.5 ppm (N(CH₃)₂) 44.3 ppm (—CH₂—, very broad), 33.3 ppm (NC(CH₃)₃), 3.1 ppm (Si(CH₃)₃). Elemental analysis for C₂₁H₄₆N₅Si₂Nb Theoretical: C, 48.72; H, 8.96; N, 13.53 Found: C, 48.57; H, 8.87; N, 13.39. EI-MS (assignment, % relative intensity): 514 [{M-C₇H₇}⁺, 100.0], 471 [{M-C₇H₇—NMe₂}⁺, 6.6], 91 [(C₇H₇}⁺, 23.3], 73 E(SiMe₃}⁺, 26.1], 58 [{NNMe₂}, 7.8]. IR (nujol mull, cm⁻¹): 2822 m, 2776 m, 1396 m, 1352 m, 1249 s, 1213 m, 1134 m, 1055 s, 1033 s, 964 s, 896 s, 839 s, 773 m, 748 m, 681 m, 634 w, 575 w, 527 m, 481 m.

### Example 10

### Preparation of [Ta(NtBu)(N(SiMe₃)NMe₂)₂)(NMe₂)]

300 ml of toluene were added to a mixture of 30.32 g (50.9 mmol) of [Ta(NtBu) (N(SiMe₃)NMe₂)₂)Br] (Example 4) and 2.86 g (56.1 mmol) of LiNMe₂ at 0° C. After one hour, stirring was effected for 10 hours at 23° C. The reaction mixture was filtered and the residue was washed with 150 ml of hexane. The combined filtrates were evaporated to dryness and the residue was sublimed (90° C., 10⁻³ mbar).

Yield: 24.86 g (44.5 mmol, 87%). ¹H-NMR (300 MHz, C₆D₆): 3.43 ppm (s, 6H, Ta—N(CH₃)₂), 2.53 ppm (s, 6H, N(CH₃)₂), 2.40 ppm (s, 6H, N(CH₃)₂), 1.50 ppm (s, 9H, NC(CH₃)₃), 0.34 ppm (s, 9H, Si(CH₃)₃). ¹³ C{¹H}-NMR (75 MHz, C₆D₆): 63.2 ppm (NC(CH₃)₃), 51.6 ppm (Ta—N(CH₃)₂), 51.3 ppm (N(CH₃)₂), 50.5 ppm (N(CH₃)₂), 35.0 ppm (NC(CH₃)₃), 3.5 ppm (Si(CH₃)₃). Elemental analysis for C₁₆H₄₅N₆Si₂Ta Theoretical: C, 34,40; H, 8.12; N, 15.04; Found: C, 34.27; H, 7.92; N, 15.14. EI-MS (assignment, % relative intensity): 558 [{M}⁺, 5.5], 543 [{M-CH₃}⁺, 50.5], 501 [{M-C₄H₉}⁺, 33.3], 132 [{HN(SiMe₃)NMe₂}⁺, 15.0], 131 [{N(SiMe₃)NMe₂}⁺, 9.0], 73 [{SiMe₃}⁺, 100.0], 58 [{NNMe₃}, 54.1], 44 [{NMe₂}, 20.5]. IR (nujol mull, cm⁻¹): 2810 s, 2758 s, 1350 m, 1275 s, 1244 s, 1211 m, 1157 m, 1053 s, 1031 s, 964 s, 895 s, 837 s, 775 s, 717 m, 682 s, 634 m, 540 s, 474 m.

### Example 11

### Preparation of a Ta-Containing CVD Layer According to the Invention

After customary pretreatment, an Si wafer (manufacturer: Wacker, Virginia Semiconductor or G-Material) was inserted into a CVD apparatus (type Aix 200 of manufacturer Aixtron AG). First, a thermal heating step for the Si wafer was effected in a customary manner for purification purposes at 750° C. in an inert carrier gas stream. The wafer was then cooled to a substrate temperature of 500° C. A layer of the Ta starting substances according to the invention was deposited on the surface thus obtained. For this purpose, an inert gas stream of N₂ was laden with the various starting materials. The following were used as starting materials: [Ta(NtBu)(N(SiMe₃)NMe₂)₂ (NMe₂)] (Example 10) and 1,1-dimethylhydrazine, 1,1-dimethylhydrazine being commercially available in the purity suitable for CVD (for example from Akzo Nobel HPMO).

For the production of Ta-containing layers according to the invention, for example, the following conditions were chosen at a total pressure of the CVD reactor of 100 hPa: 0.00005 hPa [Ta(NtBu)(N(SiMe₃)NMe₂)₂(NMe₂)] (Example 10), 3 hPa 1,1-dimethylhydrazine. The N/Ta ratio was thus chosen as 60 000. The laden N₂ carrier gas stream at a total pressure of 100 hPa was then passed for the duration of 4 h over the surface of the Si wafer heated to 500° C. A layer according to the invention having a thickness of 85 nm was obtained. After expiry of the duration of exposure, the CVD unit was changed over to the deposition conditions of a desired further layer, or the layer was cooled under an inert carrier gas stream and removed from the CVD reactor.

### Example 12

### Preparation of [Nb(NtBu)(N(SiMe₃)NMe₂)₂(NMe₂)]

A solution of 164 mg (3.3 mmol) of LiNMe₂ in 15 ml of toluene was added to 1.5 g (3.2 mmol) of [Nb(NtBu)(N(SiMe₃)NMe₂)₂)Br] (Example 5) at 0° C. After one hour, stirring was effected for 10 hours at 23° C. The reaction mixture was filtered and the residue of the filtrates on evaporation was sublimed (100° C., 10⁻³ mbar).

Yield: 1.12 g (2.4 mmol, 73%). ¹H-NMR (300 MHz, C₆D₆): 3.40 ppm (s, 6H, Ta—N(CH₃)₂), 2.51 ppm (s, 6H, N(CH₃)₂), 2.41 ppm (s, 6H, N(CH₃)₂), 1.46 ppm (s, 9H, NC(CH₃)₃), 0.34 ppm (s, 9H, Si(CH₃)₃). ¹³C{¹H}-NMR (75 MHz, C₆D₆): 52.0 ppm (Ta—N(CH₃)₂), 51.2 ppm (N(CH₃)₂), 50.57 ppm (N(CH₃)₂), 33.7 ppm (NC(C₆H₃)₃), 3.5 ppm (Si(CH₃)₃). EI-MS (assignment, % relative intensity): 470 [{M}⁺, 1.7], 412 [{M-NN(CH₃)₂}⁺, 5.7], 367 [{M-NN(CH₃)₂—HN(CH₃)₂}⁺, 33.31, 132 [{HN(SiMe₃)NMe₂}⁺, 3.0], 131 [{N(SiMe₃)NMe₂}⁺, 3.0], 73 {{SiMe₃}⁺, 48.9], 58 [{NNMe₂}, 54.1], 44 [{NMe₂}, 20.5]. Elemental analysis for C₁₆H₄₅N₆Si₂Ta Theoretical: C, 34.40; H, 8.12; N, 15.04 Found: C, 40.37; H, 9.55; N, 17.74. IR (nujol mull, cm⁻¹): 2754 s, 1352 w, 1247 s, 1210 w, 1155 w, 1131 w, 1053 s, 1032 s, 958 s, 892 s, 837 s, 777 m, 716 m, 681 m, 634 w, 552 w, 476 w.

### Example 13

### Preparation of [Ta(NtBu)(N(H)tBu)(N(SiMe₃)NMe₂)₂]

a) 5 ml of toluene were added to 306 mg (0.54 mmol) of [Ta(NtBu)(N(SiMe₃)NMe₂)₂Br] (Example 4) and 55 mg (0.69 mmol) of LiN(H)tBu at 0° C. After 30 minutes, the mixture was brought to 23° C. and stirred for a further 10 hours. The suspension was filtered and the residue was washed with 5 ml of hexane. The combined filtrates were evaporated to dryness and sublimed (100° C., 10⁻³ mbar). Yield: 220 mg (0.36 mmol, 67%).

b) 20 ml of THF were added to 4.0 g (7.23 mmol) of [Ta(NtBu)(N(H)tBu)Cl₂Py₂] (Example D) and 3.4 g (14.44 mmol) of [Mg(N(SiMe₃)NMe₂)Br] (Example B) at −78° C. After one hour, the mixture was heated to room temperature and stirred for a further 12 hours. The suspension was freed from volatile constituents at 20 mbar and the residue was extracted with 40 ml of hexane. The filtration residue was washed twice with 10 ml of hexane. The combined filtrates were evaporated to dryness and sublimed (100° C., 10⁻³ mbar).

Yield: 2.77 g (4.72 mmol, 65%). ¹H-NMR (300 MHz, C₆D₆): 3.00 (s, 1H, HNtBu), 2.60 ppm (s, 6H, N(CH₃)₂), 2.35 ppm (s, 6H, N(CH₃)₂), 1.54 ppm (5, 9H, NC(CH₃)₃), 1.52 ppm (s, 9H, NC(CH₃)₃), 0.32 ppm (s, 9H, Si(CH₃)₃). ¹³C {1H}-NMR (75 MHz, C₆D6): 63.4 ppm (NC(CH₃)₃), 52.8 ppm (NC(CH₃)₃), 50.4 ppm (Ta—N(CH₃)₂), 49.7 ppm (N(CH₃)₂), 35.8 ppm (NC(CH₃)₃), 35.1 ppm (NC(CH₃)₃), 3.4 ppm (Si(CH₃)₃). EI-MS (assignment, % relative intensity): 529 [{M-C₄H₉}⁺, 9.7], 131 [{N(SiMe₃)NMe₂}⁺, 20.6], 73 [{SiMe₃}⁺, 100.0], 57 [{C₄H₉}⁺, 8.8], 44 [{NMe₂}, 47.0]. Elemental analysis for C₁₈H₄₉N₆Si₂Ta Theoretical: C, 36.85; H, 8.42; N, 14.32 Found: C, 14.26; H, 8.34; N, 14.31. IR (nujol mull, cm⁻¹): 2724 w, 1351 w, 1271 s, 1245 s, 1211 m, 1052 s, 1029 s, 979 m, 896 s, 837 s, 774 m, 724 bm, 682 m, 530 w, 475 w.

### Example 14

### Preparation of [Nb(NtBu)(N(H)tBu)(N(SiMe₃)NMe₂)₂]

a) 15 ml of toluene were added to a mixture of 1.52 g (3.29 mmol) of [Nb(NtBu) (N(SiMe₃)NMe₂)₂Br] (Example 5) and 256 mg (3.21 mmol) of LiN(H)tBu at 0° C. After 30 minutes, the mixture was heated to 23° C. and stirred for 10 hours. The suspension was filtered and the residue was washed with twice 5 ml of hexane. The filtrates were combined and brought to dryness. The residue on evaporation was sublimed (100° C., 10⁻³ mbar). Yield: 1.08 g (2.16 mmol, 67%).

b) 200 ml of THF were added to 10.0 g (21.6 mmol) of [Nb(NtBu)(N(H)tBu)Cl₂Py₂] (prepared analogously to Example D) and 10.1 g (43.0 mmol) of [Mg(N(SiMe₃)NMe₂)Br] (Example B) at −78° C. After one hour, the mixture was brought to 23° C. and stirred for 12 hours, The suspension was evaporated to dryness and extracted with 200 ml of hexane. The residue was washed twice with 50 ml of hexane. The combined filtrates were freed from volatile constituents at 20 mbar and sublimed (100° C., 10⁻³ mbar).

Yield: 7.56 g (15.1 mmol, 70%). ¹H-NMR (300 MHz, C₆D₆): 3.67 (s, 1H, HNtBu), 2.57 ppm (s, 6H, N(CH₃)₂), 2.36 ppm (s, 6H, N(CH₃)₂), 1.53 ppm (s, 9H, NC(CH₃)₃), 1.48 ppm (s, 9H, NC (CH₃)₃), 0.34 ppm (s, 9H, Si (CH₃)₃). ¹³C{1H}-NMR (75 MHz, C₆D₆): 50.4 ppm (NC(CH₃)₃), 50.4 ppm (Ta—N(CH₃)₂), 49.9 ppm (N(CH₃)₂), 35.6 ppm (NC(OH₃)₃), 33.8 ppm (NC(CH₃)₃), 3.4 ppm (Si(CH₃)₃); the signals of the tertiary C atom cannot be localized exactly owing to the extreme broadening (about 63.5 ppm). EI-MS (assignment, % relative intensity): 498 [{M}⁺, 1.3], 483 [{M-CH₃}⁺, 0.11, 440 [{M-N₂C₂H₆}⁺, 13.9], 426 [{M-CH₃—C₄H₉}⁺, 18.1], 367 [(M-N(SiMe₃)NMe₂}⁺, 8.1], 351 [{M-HN(SiMe₃)NMe₂-CH₃}⁺, 3.7}, 236 [{M-2N(SiMe₃)NMe₂}⁺, 3.2], 235 [{M-N(SiMe₃)NMe₂-HN(SiMe₃)NMe₂}⁺, 4.9], 132 [{HN(SiMe₃)NMe₂}⁺, 4.4], 131 [{N(SiMe₃)NMe₂}⁺, 6.7], 73 [{SiMe}⁺, 65.4], 58 [{N₂Me₂}⁺, 60.0], 45 [{HNMe₂}⁺, 1.9]. Elemental analysis for C₁₈H₄₉N₆Si₂Nb Theoretical: C, 43.35; H, 9.90; N, 16.85. Found: C, 42.78; H, 9.99; N, 16.41. IR (nujol mull, cm⁻¹): 2725 w, 1352 w, 1246 s, 1210 m, 1053 s, 1029 s, 975 w, 892 s, 837 s, 773 m, 717 m, 681 w, 533 w, 477 w.

1-9. (canceled)

10. A Compound of the general formula (II) 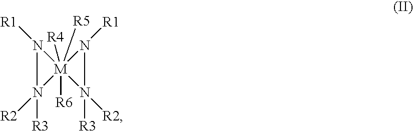
in which
M represents Nb or Ta,
R¹, R² and R³, independently of one another, represent optionally substituted C₁- to C₁₂-alkyl radicals, but not simultaneously methyl radicals, C₅- to C₁₂-cycloalkyl radicals, C₆- to C₁₀-aryl radicals, 1-alkenyl, 2-alkenyl or 3-alkenyl radicals, triorganosilyl radicals —SiR₃, in which R represents C₁- to C₄-alkyl radicals,
R⁴, R⁵ and R⁶ independently represent halogen from the group consisting of Cl, Br and I, represent O—R⁸, in which R⁸ represents an optionally substituted C₁- to C₁₂-alkyl, C₅- to C₁₂-cycloalkyl or C₆- to C₁₀-aryl radical or —SiR₃, represent BH₄, represent an optionally substituted allyl radical, represent an indenyl radical, represent an optionally substituted benzyl radical, represent an optionally substituted cyclopentadienyl radical, represent CH₂SiMe₃, represent a pseudohalide, such as, for example, —N₃, represent silylamide —N(SiMe₃)₂, represent —NR⁹R¹⁰, in which R⁹ and R¹⁰, independently of one another, represent identical or different optionally substituted C₁- to C₁₂-alkyl, C₅- to C₁₂-cycloalkyl or C₆- to C₁₀-aryl radicals, —SiR₃, in which K represents C₁-C₄-alkyl, or H, or represents —NR¹—NR²R³ (hydrazido(1)), in which R¹, R² and R³, independently of one another, have the abovementioned meaning of R¹, R² and R³
or R⁴ and R⁵ together represent ═N—R⁷, in which R⁷ represents an optionally substituted C₁- to C₁₂-alkyl, C₆- to C₁₂-cycloalkyl or C₆- to C₁₀-aryl radical or —SiR₃.

11. The compound according to claim 10, wherein the compound is of the general formula (III) 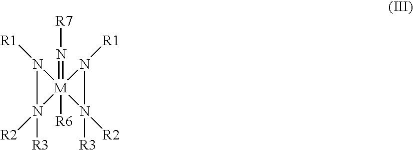
in which
M represents Ta or Nb,
R¹ represents C₁- to C₅-alkyl, C₅- to C₆-cycloalkyl or an optionally substituted phenyl radical or SiR₃, in which R represents C₁-C₄-alkyl,
R² and R³ represent identical C₁- to C₅-alkyl or C₅- to C₆-cycloalkyl radicals or optionally substituted phenyl radicals or SiR₃, in which R represents C₁-C₄-alkyl,
R⁷ represents a C₁- to C₅-alkyl, C₅- to C₆-cycloalkyl or optionally substituted phenyl radical or SiR₃, in which R represents C₁-C₄-alkyl, and
R⁶ represents a halogen radical from the group consisting of Cl, Br and I, represents BH₄, represents an optionally substituted allyl radical, represents an indenyl radical, represents an optionally substituted benzyl radical, represents an optionally substituted cyclopentadienyl radical, represents a C₁- to C₁₂-oxyalkyl radical or represents a radical —NR⁹R¹⁰, in which R⁹ and R¹⁰, independently of one another, represent identical or different optionally substituted C₁- to C₁₂-alkyl, C₅- to C₁₂-cycloalkyl or C₆- to C₁₀-aryl radicals, —SiR₃, in which R represents C₁-C₄-alkyl, or H.

12. The compound according to claim 10, wherein the compound is of the general formula (IV) 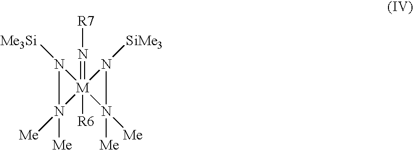
in which
R⁷ represents a radical from the group consisting of the C₁- to C₅-alkyl radicals, the C₆- to C₁₀-aryl radicals optionally substituted by one to three C₁- to C₅-alkyl groups, or SiR₃, in which R represents C₁-C₄-alkyl, and
R⁶ represents a halogen radical from the group consisting of Cl, Br and I, represents BH₄, represents an optionally substituted allyl radical represents an indenyl radical, represents an optionally substituted benzyl radical, represents an optionally substituted cyclopentadienyl radical, represents a C₁- to C₁₂-oxyalkyl radical or represents a radical —NR⁹R¹⁰, in which R⁹ and R¹⁰, independently of one another, represent identical or different optionally substituted C₁- to C₁₂-alkyl, C₅- to C₁₂-cycloalkyl or C₆- to C₁₀-aryl radicals, —SiR₃, in which R represents C₁-C₄-alkyl, or H.

13. The compounds according to claim 10, wherein the compound is of the general formula (V) 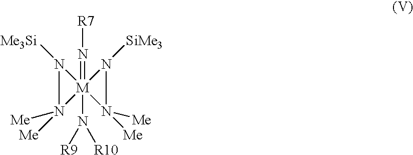
in which
R⁹ and R¹⁰ independently of one another, represent an identical or different radical from the group consisting of the C₁- to C₅-alkyl radicals, C₆-C₁₀-aryl radicals optionally substituted by one to three C₁-C₅-alkyl groups, or SiR₃, in which R represents C₁-C₄-alkyl, or H and
R⁷ represents a radical from the group consisting of the C₁- to C₅-alkyl radicals, C₆-C₁₀-aryl radicals optionally substituted by one to three C₁- to C₅-alkyl groups, or SiR₃, in which R represents C₁-C₄-alkyl.

14. The compounds according to at least one of claim 10, wherein the compound is of the general formulae (VI) to (X) 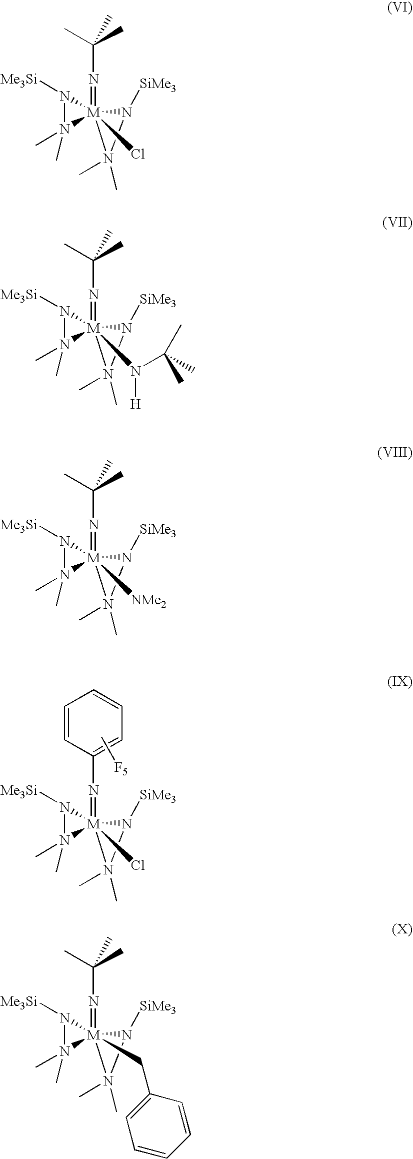
in which M represents Ta or Nb and
Me is CH₃.

15. The compound according to claim 14, wherein M is Nb.

16. A precursor for the production of tantalum- or niobium-containing layers by means of the chemical vapor deposition process which comprises the compound as claimed in claim 10.

17. A process to produce tantalum nitride (TaN) layer or niobium nitride (NbN) layer which comprises utilizing a chemical vapor deposition process with a precursor comprising the compound as claimed in claim 10.

18. A layer produced according to claim 17.

19. A substrate having a layer produced from a compound of claim 10, by means of the chemical vapor deposition process.
